(19) United States
(12) Patent Application Publication
(10) Pub. No.: US 2005/0239272 A1
(43) Pub. Date: Oct. 27, 2005

(54) Process for producing a multilayer arrangement having a metal layer

(75) Inventors: Eike Ruttkowski, Munchen (DE); Gurkan Ilicali, Munchen (DE); Richard Johannes Luyken, Munchen (DE); Franz Hofmann, Munich (DE); Manuela Alba Bueno, Munchen (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/920,043

(22) Filed: Aug. 16, 2004

(30) Foreign Application Priority Data
Aug. 18, 2003 (DE) 103 37 830.8

(51) Int. Cl. H01L 21/44

(52) U.S. Cl. 438/597; 438/670

(57) ABSTRACT

Process for producing a multilayer arrangement having a metal layer, in which a metal layer is applied to a surface of a first wafer and at least one interlayer is applied to the metal layer. Furthermore, a second wafer is applied to the interlayer and then the first wafer is removed, so that the metal layer is uncovered.

### CROSS-REFERENCE TO RELATED APPLICATION

This application is claims priority to German Patent Application Serial No. 103 37 830.8, filed Aug. 18, 2003.

### FIELD OF THE INVENTION

The invention relates to a process for producing a multilayer arrangement having a metal layer.

### BACKGROUND OF THE INVENTION

In recent times, as part of the efforts to achieve ever smaller feature sizes in electronics, organic molecules have come to the fore as “miniature switches” for electronic components. Ultra-flat patterned metal bonding layers are required for the integration and electrical contact-connection of molecular systems in molecular electronics and in biosensor technology. The metal used in this case is in particular gold, since the molecular systems, i.e. organic molecules, are often provided with thiol end groups, and what is known as the sulfur-gold coupling has good properties. Since the molecules which are used in molecular electronics are often no longer than 1 to 2 nm, metallic bonding layer roughnesses of better than 0.5 nm are required. The deposition of layers with a surface quality of this type, i.e. with such a low roughness, or in other words with an ultra-flat surface, can only be achieved with difficulty, since nucleation which increases the roughness of the surface usually occurs during deposition of the material. Furthermore, the patterning of layers of this type also presents problems, since surfaces which are excessively rough may occur in particular at the etched edges.

To form ultra-flat gold structures of this type, the prior art has disclosed processes which apply the layer of gold by means of atomic layer deposition (ALD) or by means of physical vapor deposition (PVD). Patterning of this gold layer is generally carried out by means of etching, which can be carried out as wet or dry etching, or by means of a lift-off process, i.e. by means of a process in which first of all a photoresist is applied to the entire surface of a substrate, is then patterned and is then metallically coated over the entire surface, so that direct coating between substrate and metal takes place at the locations which are not covered with photoresist.

The nucleation of the gold during the deposition means that the known processes often lead to an unfavorable topology, i.e. to an excessively rough surface of the gold layer.

Another process which is known from the prior art is known from Ultralarge atomically flat template-stripped Au surfaces for scanning probe microscopy, M. Hegner, P. Wagner and G. Semenza, Surface Science 291 (1993) 39-46. In this process, to produce ultra-flat gold layers a layer of gold is applied to a thin mica, produced by cleaving the mica. Then, the mica layer is stripped. However, one drawback of this process is that it is restricted to small areas, since the size of mica available is only small. In addition, this process can only be incorporated in the standard semiconductor processing steps with difficulty.

U.S. 2002/0025668 has disclosed a process for forming a structured metallization on a wafer which uses a transfer process including a transfer step in which a first substrate which has a metallic wiring layer that is to be transferred is thermally pressed onto the wafer.

Low-Temperature Wafer-Level Transfer Bonding, F. Niklaus et al., Journal of Microelectronical Systems Vol. 10, No. 4 (December 2001) 525-531, has disclosed a process allowing devices or films to be transferred from a sacrificial substrate to a target substrate by means of bonding technology.

DE 102 51 229 has disclosed conjugates formed from dithiolane derivatives with organic-chemical or biological-chemical molecules, processes for producing the dithiolane derivatives and the conjugates, a coated precious metal or semiconductor structure which includes a conjugate or a dithiolane derivative immobilized on it, and a biochip which includes a precious metal or semiconductor structure of this type.

U.S. Pat. No. 5,512,131 has disclosed a process for patterning a surface of a material in which an elastomeric ram with a ram surface is coated with a monolayer of a material which includes a functional group that bonds to a specific material, and in which the ram surface is placed onto a surface and removed, leaving behind a monolayer corresponding to the ram surface.

WO 01/27972 has disclosed molecular systems which have at least two conductive contacts and a bridging conductive path between the contacts, the conductive path including organic molecules.

### SUMMARY OF THE INVENTION

The invention is based on the problem of providing a simplified and improved process for producing a large-area multilayer arrangement having a metal layer, which metal layer has a low roughness, in which process it is possible to use known and simple process steps from semiconductor processing technology.

In a process according to the invention for producing a multilayer arrangement having a metal layer, a metal layer is applied to a surface of a first wafer, and at least one interlayer is applied to the metal layer. Furthermore, a second wafer is applied to the interlayer, and then the first wafer is removed, so that the metal layer is uncovered.

The process according to the invention for producing a multilayer arrangement having a metal layer has the advantage that, by virtue of the use of a wafer, instead of a mica it is possible to form a larger-area metal layer of low roughness, i.e. with an ultra-flat surface. Furthermore, operations involving a wafer are easier to integrate in the standard processing steps carried out within semiconductor processing. An additional advantage is that the metal layer applied to the first layer can be patterned or can be applied in patterned form.

Evidently, the invention can be considered as residing in the fact that for the first time it has been made possible to ensure an ultra-flat surface of the metal layer as part of standard processing of a wafer using technologies which are known per se. This is achieved by virtue of the surface structure of the wafer substrate material, preferably silicon, being transferred to the lower surface of the applied metal layer.

Preferred refinements of the invention will emerge from the dependent claims.

It is preferable for the metal layer to include gold, silver or platinum.

The use of gold, silver or platinum for the metal layer has the advantage that all these metals readily form a stable bond with sulfur. In particular the gold-sulfur coupling has proven particularly suitable for immobilization within molecular systems and has also already formed the subject of detailed investigations.

One additional advantage of the abovementioned metals is that they all exhibit poor bonding to silicon, and silicon is a standard material for the first wafer. It is therefore easy to remove the first wafer without damaging the metal layer, since the metal layer does not bond as well to the first wafer as it does to the interlayer and/or the second wafer. By way of example, the gold of the metal layer does not bond as well to the first wafer as it does to the material of the interlayer or the second wafer. In principle, all materials which on the one hand do not bond as well to the first wafer as to the material of the interlayer and/or to the material of the second wafer and, on the other hand, have good properties for use within molecular systems, can be used for the metal layer.

It is preferable for the first wafer and/or the second wafer to be produced from at least one of the materials selected from the group consisting of silicon, gallium arsenide, silicon-germanium, indium-gallium arsenide, indium-antimony, zinc sulfide, gallium-aluminum arsenide, gallium-aluminum phosphide or gallium phosphide.

The use of the materials disclosed is particularly advantageous since on the one hand they are standard materials used in semiconductor processing and on the other hand the materials also have a greater hardness than the metal layers which are customarily used and can therefore also be polished more easily, making it possible to produce the desired low surface roughness. In principle, it is possible to use all materials which can be planarized as well as the abovementioned materials, preferably be means of chemical mechanical polishing;

In a refinement, the second wafer includes electronic components.

Electronic circuits can be built up in a simple way by virtue of the fact that the second wafer may include electronic components. The electronic components may be arranged in or on the second wafer even before the second wafer is applied. The metal layer of the multilayer arrangement may, for example, be used as a contact-connection or immobilization arrangement within a molecular system whose electronic circuits are arranged in or on the second wafer. In this context, however, it should be noted that under certain circumstances vias are to be provided in the second wafer and/or the interlayer for contact-connection of the metal layer, and that the second wafer and/or the interlayer are also to be applied to the first wafer in an aligned arrangement, in such a way that the vias also contact-connect the metal layer.

It is preferable for the metal layer to be formed as a patterned metal layer.

This allows versatile use of the patterned metal layer, for example as part of electronic circuits or as contact-connection for various electronic components.

It is particularly preferable for a mask formed from an electrically insulating material to be formed on the surface of the first wafer prior to application of the metal layer.

This makes it possible in a particularly simple way for the metal layer to be formed in patterned form on the wafer. The mask made from electrically insulating material can be used as a positive mask for the application of the patterned metal layer. Since the mask is produced from an electrically insulating material, it can remain part of the multilayer arrangement even after the patterned metal layer has been formed and does not need to be removed.

The mask may be formed from silicon nitride (Si₃N₄), silicon oxide (SiO₂), hafnium oxide (HfO) or aluminum oxide (Al₂O₃) on the surface of the first wafer.

Materials which can be used as a stop layer in an etching process are particularly suitable for use as materials for the mask. There are numerous suitable combinations of metal, mask material and etchant used for this purpose. By way of example, the combination of gold, silicon nitride and TMAH (tetramethylammonium hydroxide) is eminently suitable for this purpose, since TMAH does not etch either gold or silicon nitride. Other suitable combinations include gold, silicon nitride (Si₃N₄) and potassium hydroxide (KOH), or gold, silicon nitride (Si₃N₄) or silicon oxide (SiO₂) and ammonium hydroxide (NH₄OH).

A second metal layer may preferably be formed on the metal layer prior to application of the at least one interlayer.

The second metal layer can serve as a bonding layer and thereby leads to an improvement in the bonding of the first metal layer.

It is particularly preferable for the second metal layer to include titanium, palladium, chromium or hafnium.

In a refinement, the second wafer is applied by means of wafer bonding.

Wafer bonding provides a process for joining together two wafers which is simple to carry out. All conventional wafer bonding processes, such as for example adhesive wafer bonding or anodic wafer bonding, are suitable for carrying out the wafer bonding.

The first wafer can be etched.

Etching represents a simple process for removal of the first wafer in order thereby to uncover the metal layer of the multilayer arrangement. In particular, as mentioned above, etching is advantageous in certain combinations of metals of the metal layer and the material of the mask.

In a refinement, the interlayer is produced from an epoxy resin.

The second wafer can be applied by means of adhesive bonding.

It is preferable for the first wafer to be etched or chemically stripped.

Stripping of the first wafer represents a simple process for removal of the first wafer. Stripping is simple to carry out in particular when using a metal, for example gold, which bonds less well to the first wafer, e.g. a silicon wafer, than to the material of the interlayer and/or the material of the second wafer.

With the described process for producing a multilayer arrangement having a metal layer, a metal layer with an ultra-flat surface, i.e. a very low roughness, is created by means of simple, known, tried-and-tested and inexpensive process steps. A roughness of less than 0.5 nm, as is required in molecular electronics applications to allow the metal layer to be used, can be achieved by means of the process, i.e. the process produces a metal layer with a roughness of less than 0.5 nm. Even roughnesses of less than 0.2 nm can be achieved by the process according to the invention.

The process according to the invention evidently consists in the very low roughness of a surface of a wafer being imparted to a metal layer. As a result, it is possible to produce a metal layer, e.g. a gold structure, with a very low roughness, i.e. an ultra-flat metal layer, in a simple way. For this purpose, the metal structure is simply applied to, preferably deposited on, the wafer surface, which has a very low roughness. If the wafer which is to be used for the process according to the invention does not have the desired roughness, it is easy to polish the surface of the wafer before the metal layer is applied, in order to obtain the desired roughness. This can be achieved, for example, by means of chemical mechanical polishing. In addition, it is possible to make use of the relative inability of a metal layer, e.g. gold, to bond to a wafer, e.g. a silicon wafer, to allow simple removal of this wafer, in order in this way to uncover the metal surface to which the low roughness has been imparted in a simple way.

The uncovered metal surface with a low roughness can then be used, for example, to immobilize capture molecules and to form what is known as a biochip, by means of which biomolecules, for example DNA molecules, can be detected using what are known as hybridization events, i.e. the biomolecules accumulate at the capture molecules, and are hybridized, with the result that properties, such as for example capacitance or electrical resistance, of the biochip change. The metal surface according to the invention is particularly suitable for a biochip or a molecular electronics arrangement, since the properties, such as for example the sensitivity of the molecular electronics arrangement and the reproducibility of the measurements, are improved by the low roughness of the metal surface.

All conventional, suitable etching processes can be used for the etching.

### BRIEF DESCRIPTION OF THE DRAWINGS

Exemplary embodiments of the invention are illustrated in the figures and are explained in more detail in the text which follows.

FIG. 1 shows a diagrammatic cross-sectional illustration of a layer arrangement which includes a first wafer and a silicon nitride layer;

FIG. 2 shows a diagrammatic cross-sectional illustration of the layer arrangement from FIG. 1 following patterning of the silicon nitride layer;

FIG. 3 shows a diagrammatic cross-sectional illustration of the layer arrangement shown in FIG. 2 following the formation of a first metal layer;

FIG. 4 shows a diagrammatic cross-sectional illustration of the layer arrangement shown in FIG. 3 following the formation of a second metal layer;

FIG. 5 shows a diagrammatic cross-sectional illustration of the layer arrangement shown in FIG. 4 following removal of parts of the metal layer and of the second metal layer;

FIG. 6 shows a diagrammatic cross-sectional illustration of the layer arrangement shown in FIG. 5 following the formation of a silicon oxide layer;

FIG. 7 shows a diagrammatic cross-sectional illustration of the layer arrangement shown in FIG. 6 following bonding of a second wafer to the silicon oxide layer;

FIG. 8 shows a diagrammatic cross-sectional illustration of the layer arrangement shown in FIG. 7 following removal of the first wafer;

FIG. 9 shows a diagrammatic cross-sectional illustration of the layer arrangement shown in FIG. 1 following substeps of a second exemplary embodiment in which a photoresist is formed on the silicon nitride layer;

FIG. 10 shows a diagrammatic cross-sectional illustration of the layer arrangement shown in FIG. 9 following the formation of a first metal layer;

FIG. 11 shows a diagrammatic cross-sectional illustration of the layer arrangement shown in FIG. 10 following the formation of a second metal layer;

FIG. 12 shows a diagrammatic cross-sectional illustration of the layer arrangement shown in FIG. 11 following lift-off of the photoresist layer and of the first and second metal layers which are present thereon;

FIG. 13 shows a diagrammatic cross-sectional illustration of a layer arrangement of a third exemplary embodiment, which includes a first wafer and a metal layer;

FIG. 14 shows a diagrammatic cross-sectional illustration of the layer arrangement shown in FIG. 13 following substeps of the third exemplary embodiment in which an epoxy resin layer has been applied;

FIG. 15 shows a diagrammatic cross-sectional illustration of the layer arrangement shown in FIG. 14 following substeps of the third exemplary embodiment in which a second wafer has been applied;

FIG. 16 shows a diagrammatic cross-sectional illustration of the layer arrangement shown in FIG. 15 following substeps of the third exemplary embodiment in which the first wafer is detached; and

FIG. 17 shows a plan view of a multilayer arrangement having a metal layer, revealing the metal layer with a low roughness.

### DETAILED DESCRIPTION OF PREFERRED EMBODIMENTS OF THE INVENTION

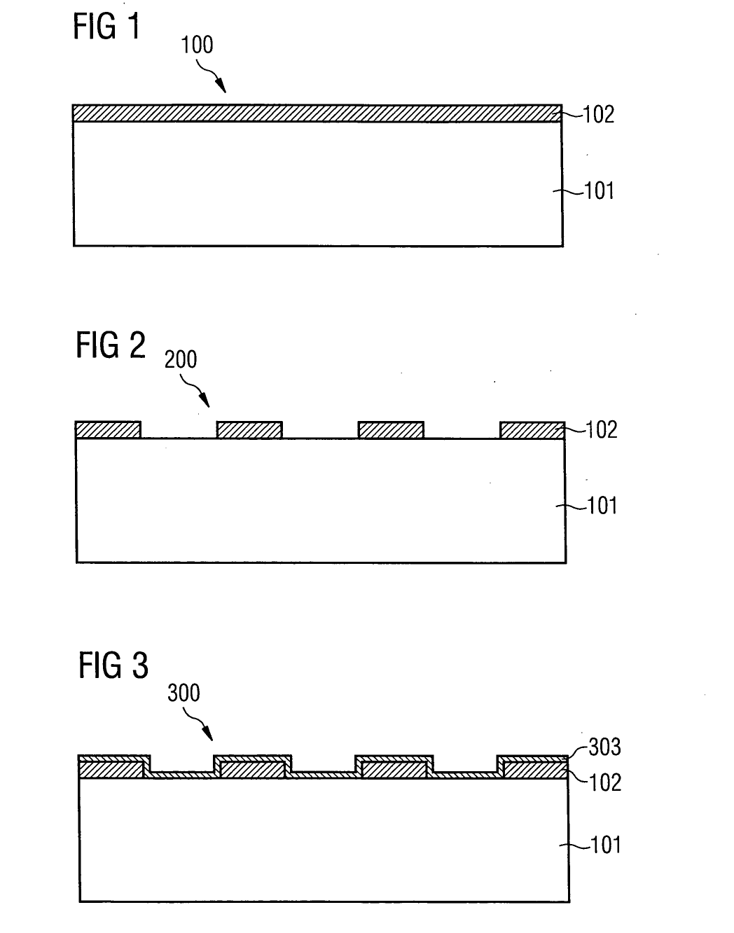

The main substeps of a first exemplary embodiment of the process for producing a multilayer arrangement having a metal layer will now be explained with reference to FIGS. 1 to 8.

FIG. 1 shows a layer arrangement 100 which has a first wafer 101. A silicon nitride layer 102 is deposited on the first wafer 101. In accordance with this exemplary embodiment, the first wafer 101 is a silicon wafer. The thickness of the deposited silicon nitride layer is preferably less than 150 nm, particularly preferably less than 50 nm since a silicon nitride layer which is deposited on a silicon layer and is thicker than 50 nm causes mechanical stress. However, to reduce the mechanical stress it is also possible to oxidize the silicon wafer before the silicon nitride layer is deposited, so that the silicon nitride layer 102 is deposited on silicon oxide. Deposition of the silicon nitride layer on silicon oxide also makes it possible to form thicker silicon nitride layers, i.e. silicon nitride layers which are thicker than 50 nm, on the silicon wafer without causing excessive mechanical stress.

FIG. 2 shows the layer arrangement from FIG. 1 following additional substeps of the process for producing a multilayer arrangement having a metal layer. The silicon nitride layer 102 is patterned as a result of a photoresist layer being applied and exposed. The patterning of the silicon nitride layer 102 is carried out by means of an anisotropic etching process, such as for example reactive ion etching (RIE). The patterning of the silicon nitride layer 102 serves to allow the structured silicon nitride layer 102 subsequently to be used as a positive mask for the desired structures of the first metal layer. The regions of the silicon nitride layer 102 which are subsequently intended to have the metal structures are etched. Then, the photoresist layer is removed.

FIG. 3 shows a layer arrangement 300 following additional substeps of the process according to the invention for producing a multilayer arrangement having a metal layer. A first metal layer of gold 303 is formed on the layer arrangement 200 shown in FIG. 2. This can be carried out, for example, by means of sputtering, deposition or evaporation coating. The thickness of the gold layer 303 must in this case be less than the thickness of the silicon nitride layer 102.

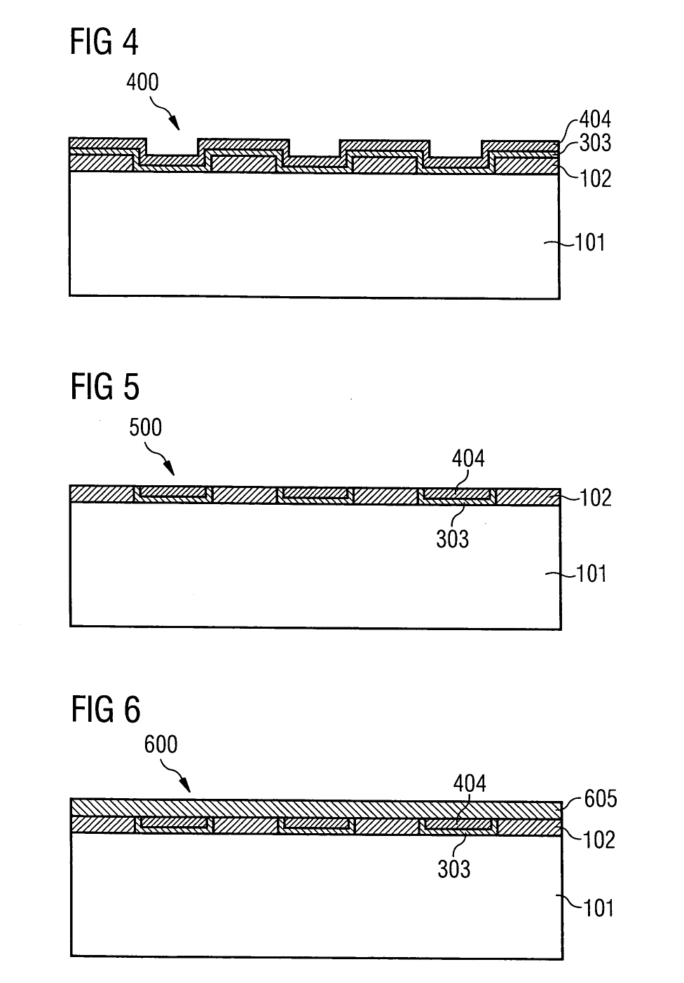

FIG. 4 shows a layer arrangement 400 following additional substeps of the process according to the invention for producing a multilayer arrangement having a metal layer. A titanium layer 404 is formed on the gold layer 303, for example by being deposited. The total thickness of the gold layer 303, which is formed directly on the first wafer, and of the titanium layer 404 formed on the gold layer, i.e. the sum of the individual thicknesses of the gold layer 303 and the titanium layer 404, is greater than the thickness of the silicon nitride layer 102 which still remains on the first wafer 101. The titanium layer 404 is used as a bonding layer.

FIG. 5 shows a layer arrangement 500 following additional substeps of the process according to the invention for producing a multilayer arrangement having a metal layer. Subregions of the titanium layer 404 and subregions of the gold layer 303 which are located on the silicon nitride layer 102 are removed by means of a planarization step, which is preferably carried out by means of chemical mechanical polishing (CMP). The planarization step on the one hand uncovers the silicon nitride layer 102 again and on the other hand also smoothes the surface of the layer arrangement.

FIG. 6 shows a layer arrangement 600 following additional substeps of the process according to the invention for producing a multilayer arrangement having a metal layer. Following the planarization, a silicon oxide layer 605 is formed on the layer arrangement. This is done by deposition. Then, the silicon oxide layer 605 is planarized, preferably by means of chemical mechanical polishing. Both the formation of the silicon oxide layer 605 and the subsequent planarization of the silicon oxide layer 605 serve to allow subsequent wafer bonding to be carried out more easily and more reliably. A typical thickness for the silicon oxide layer 605 is 1 μm.

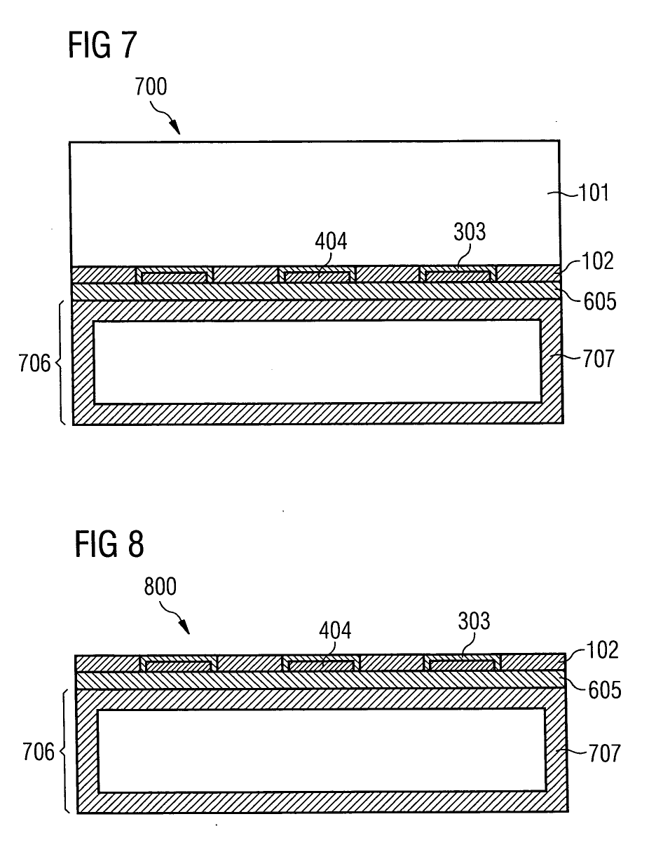

FIG. 7 shows a layer arrangement 700 following additional substeps of the process according to the invention for producing a multilayer arrangement having a metal layer. A second wafer 706 is bonded to the planarized silicon oxide layer 605. If desired, the second wafer 706 may also include electrical components which are advantageous during subsequent use of the ultra-flat metal structure in molecular electronics. It should be noted that if the second wafer 706 has electronic components which are intended to contact-connect the metal layer, the silicon oxide layer 605 must have vias at the locations at which the metal layer is to be contact-connected; in this context, it should also be noted that the second wafer and/or the interlayer should be applied to the first wafer in an alignment which is such that contact is achieved between the vias and the metal layer.

If a further etch is subsequently carried out at the layer arrangement, a protective layer 707 for the material of the second wafer 706 must also be formed if the second wafer 706 is formed from a material which is attacked by the etchant, e.g. with the combination of silicon wafer and TMAH as etchant. The formation of the protective layer 707 has to be carried out prior to bonding of the second wafer 706 to the silicon oxide layer 605. In the example, the protective layer 707 is formed from silicon oxide which is formed from the silicon of the second wafer 706 by means of thermal oxidation. The thermal oxidation allows a protective layer 707 to be formed in a simple way over the entire surface of the second wafer 706 made from silicon. However, any other process, such as for example deposition, and also any other material which is able to withstand a subsequent etch is suitable to serve as a protective layer around the second wafer 706. By way of example, it is also possible for wax, polyethylene (PE), polypropylene (PP) or polyurethane (PUR) to be used as material for the protective layer 707.

FIG. 8 shows a layer arrangement 800 following additional substeps of the process according to the invention for producing a multilayer arrangement having a metal layer. The additional substeps relate to etching back of the first wafer 101. The etching back of the first wafer 101 uncovers the patterned silicon nitride layer 102 and the patterned gold layer 303. By suitable selection of the etching process, it is possible to ensure that the etching stops at the silicon nitride layer 102 and at the gold layer 303. An example of a suitable etching process is a TMAH etch, since in this case both the silicon nitride and the gold can be used as etching stops, since both materials are stable with respect to an etch carried out using TMAH.

The substeps described with reference to FIG. 8 conclude the process for producing a multilayer arrangement having a metal layer in accordance with the first exemplary embodiment.

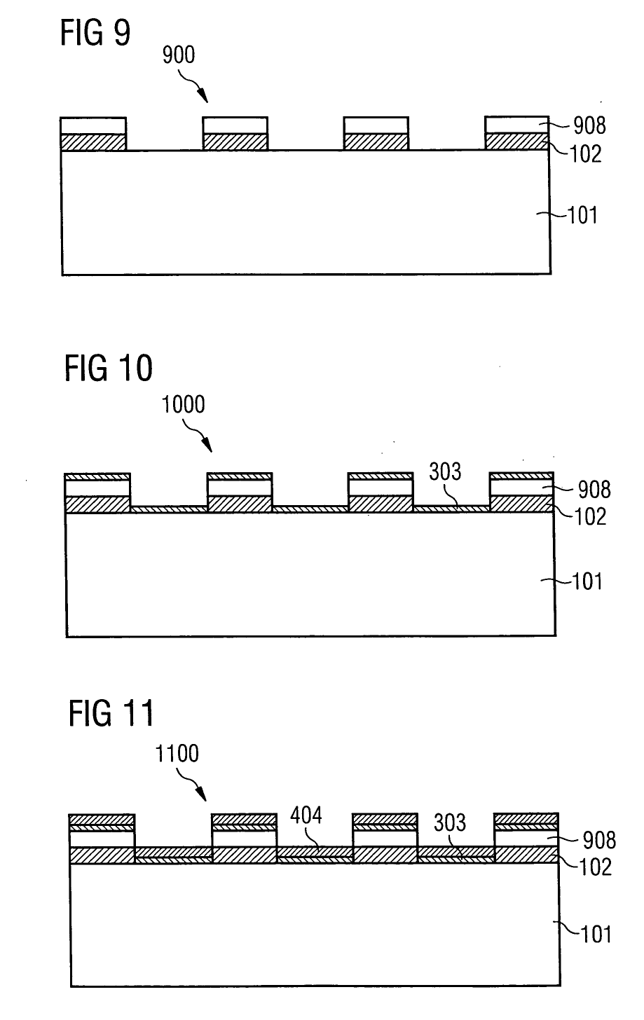

The following text describes a second exemplary embodiment of the invention, which differs from the first exemplary embodiment described above in a few substeps, with reference to FIGS. 9 to 12. In the text which follows, only those substeps of the second exemplary embodiment which differ from the corresponding substeps of the first exemplary embodiment are described.

FIG. 9, proceeding from FIG. 1, shows a layer arrangement 900 following additional substeps of the second exemplary embodiment for producing a multilayer arrangement having a metal layer. A photoresist layer 908 is formed on the silicon nitride layer 102. The photoresist layer 908 is then patterned and subsequently serves as an etching mask in an etching step which serves to pattern the silicon nitride layer 102.

FIG. 10 shows a layer arrangement 1000 following additional substeps of the second exemplary embodiment of the invention for producing a multilayer arrangement having a metal layer. A first metal layer of gold 303 is formed on the layer arrangement 900 shown in FIG. 9. This is done by means of evaporation coating. The thickness of the gold layer 303 must in this case be less than the thickness of the silicon nitride layer 102 which still remains on first the wafer 101. Furthermore, when carrying out the evaporation coating, it should be ensured that the gold which is deposited does not form a continuous layer over the entire layer arrangement, but rather the side faces of the photoresist layer 908 do not come into contact with the gold. This is also the reason why the gold layer 303 is applied not by sputtering but by evaporation coating, since sputtering would produce a continuous layer of gold.

FIG. 11 shows a layer arrangement 1100 following additional substeps of the second exemplary embodiment of the invention for producing a multilayer arrangement having a metal layer. A titanium layer 404 is formed on the gold layer 303 illustrated in FIG. 10, by means of evaporation coating. In this context, it should be ensured that the total thickness of the gold layer 303 and the titanium layer 404, i.e. the sum of the individual thicknesses of the gold layer 303 and the titanium layer 404 is less than or at most equal to the thickness of the silicon nitride layer 102 which still remains on the first wafer 101. The titanium layer 404 is used as a bonding layer. Furthermore, during deposition of the titanium by evaporation coating, it should be ensured that the titanium which is deposited also does not form a continuous layer on the entire layer arrangement, but rather the side faces of the photoresist layer 908 do not come into contact with the titanium, so that a subregion of the side faces of the silicon nitride layer 102 is not covered with metal. This is also the reason why the titanium layer 404 is applied not by sputtering but by evaporation coating, since sputtering would produce a continuous layer of titanium.

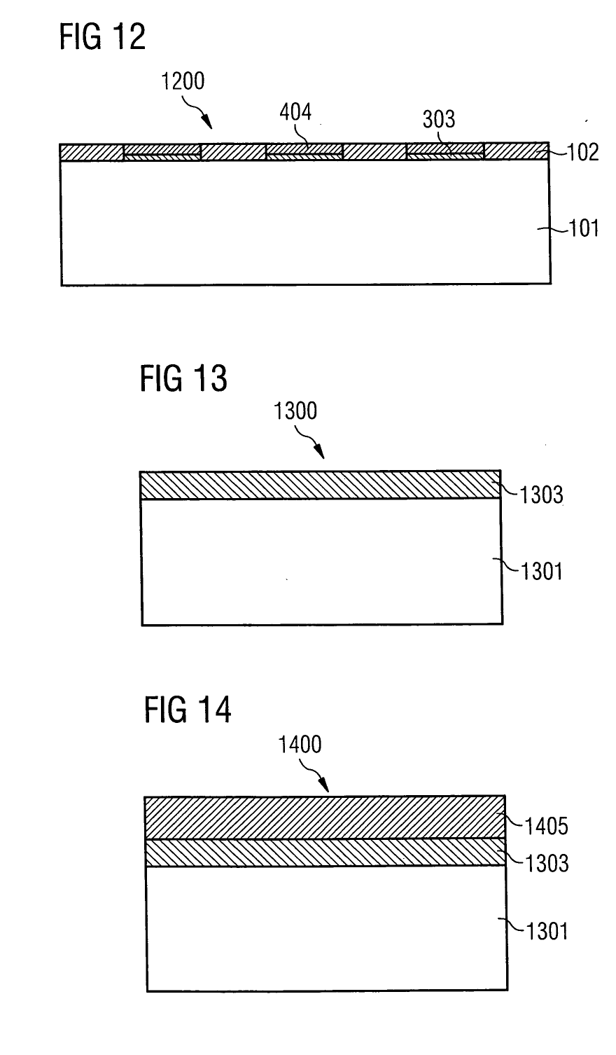

FIG. 12 shows a layer arrangement 1200 following additional substeps of the second exemplary embodiment of the invention for producing a multilayer arrangement having a metal layer. The layer arrangement 1100 shown in FIG. 11 is processed further by means of a lift-off step. The photoresist layer 908 is removed by means of the lift-off step. The subregions of the gold layer 303 and the titanium layer 404 which are arranged above the photoresist layer 908 are also removed together with the removal of the photoresist layer 908. Therefore, there is no need for the planarization step described in the first exemplary embodiment to remove these subregions of the gold layer 303 and the titanium layer 404. The use of the lift-off step to remove the photoresist layer 908 is also to be regarded as the reason why the total thickness of the gold layer 303 and the titanium layer 404 must be less than the thickness of the silicon nitride layer 102 and why the side faces of the silicon nitride layer 102 in the upper region must not come into contact with the titanium or gold, i.e. a continuous layer of metal may not be formed, since otherwise the lift-off step would remove not only the subregions of the gold layer 303 and of the titanium layer 404 located above the photoresist layer 908 but also parts of the regions of the gold layer 303 and of the titanium layer 404 which are not to be removed.

Then, in the second exemplary embodiment of the invention, the same process steps are carried out as have been explained in the first exemplary embodiment of the invention with reference to FIG. 6 to 8.

The substeps described with reference to FIG. 8 conclude the process for producing a multilayer arrangement having a metal layer in accordance with the second exemplary embodiment.

A third exemplary embodiment of the invention is explained below with reference to FIG. 13 to 17.

FIG. 13 shows a layer arrangement 1300, which includes a first wafer 1301. A first metal layer 1303 is formed on the first wafer 1301. It is preferable for the first wafer 1301 to be a silicon wafer. The metal layer 1303 is preferably deposited. It is also possible for it to be applied by sputtering or evaporation coating. The metal used is gold.

FIG. 14 shows a layer arrangement 1400 which results following additional substeps of the process for producing a multilayer arrangement having a metal layer in accordance with the third exemplary embodiment of the invention. A layer of low-viscosity epoxy resin 1405 is applied to the metal layer 1303. All known epoxy resins which contract only slightly during curing, i.e. suffer only a slight weight loss, are suitable for this purpose. Furthermore, the curing temperature of the epoxy resin should be lower than 300° Celsius; epoxy resins which cure at a temperature of from 150° to 200° Celsius are particularly preferred. In particular if gold is used as the metal layer 1303, the curing temperature must not exceed 300° Celsius, since above this temperature the gold starts to diffuse into the silicon of the wafer, with a eutectic compound being formed from approximately 363° Celsius. The use of epoxy resins with a low weight loss serves to ensure that these resins do not contract during curing, since such contraction would give rise to the formation of cracks in the epoxy resin and the metal layer beneath it.

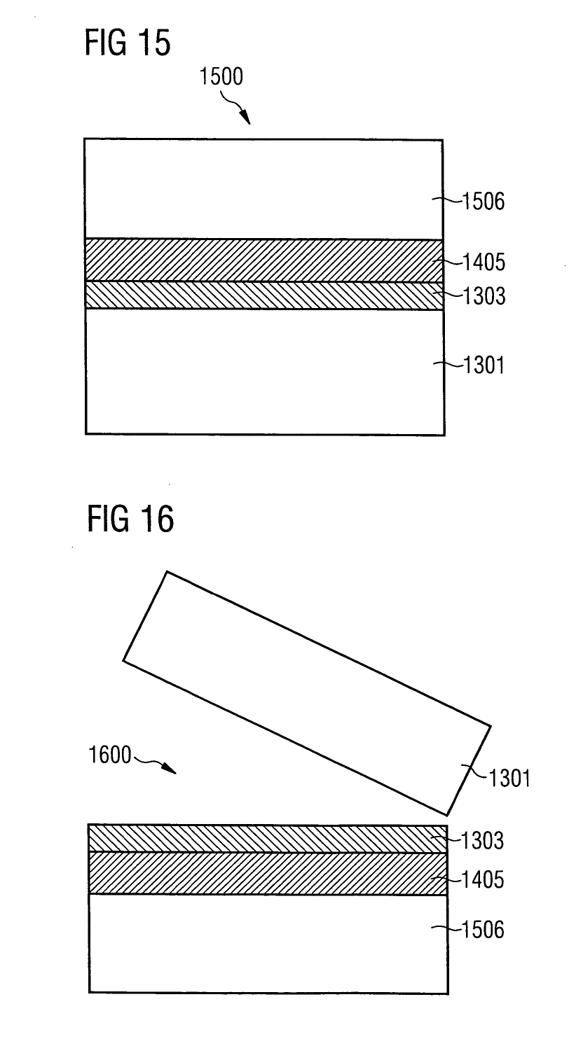

FIG. 15 shows a layer arrangement 1500 which results following additional substeps of the process for producing a multilayer arrangement having a metal layer in accordance with the third exemplary embodiment of the invention. A second wafer 1506 is applied to the epoxy resin layer 1405. Then, the epoxy resin 1405 is cured, with the result that the second wafer 1506 and the epoxy resin layer 1405 and therefore also the gold layer 1303 are fixedly joined to one another. The curing is carried out at approximately 150° Celsius.

FIG. 16 shows a layer arrangement 1600 which results following additional substeps of the process for producing a multilayer arrangement having a metal layer in accordance with the third exemplary embodiment of the invention. Next, the first wafer 1301 is detached from the gold layer 1303. This is readily possible on account of the poor bonding of the gold layer 1303 to the silicon surface of the first wafer 1301. The detachment can be carried out mechanically in a simple way by means of tensile loading.

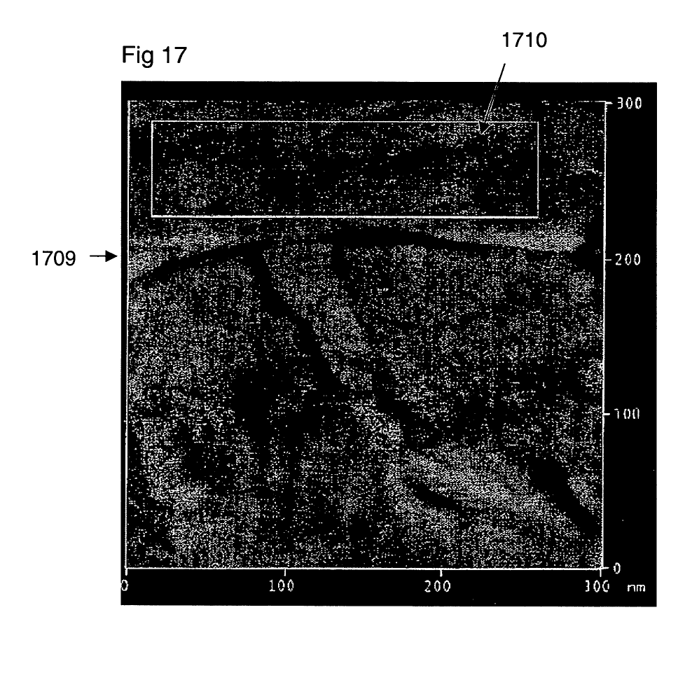

FIG. 17 shows a plan view of a specimen of a multilayer arrangement having a metal layer, which multilayer arrangement has been produced by means of a process according to the invention. The specimen was analyzed to establish the roughness of the surface of the metal layer. The surface area of the illustrated region 1709 of the specimen is 300 nm×300 nm in an X-Y plane illustrated in FIG. 17. The analysis of the roughness reveals a fluctuation range in the thickness, i.e. in the Z coordinate of FIG. 17, of 3.685 nm for the entire region illustrated in FIG. 17. This means that the measured difference in the Z coordinate from the lowest point to the highest point of the specimen is 3.685 nm. The standard deviation, i.e. the RMS value, of the Z coordinate is 0.239 nm. The absolute value of the Z coordinate is −322.48 nm. However, this absolute value has no meaning, since it merely represents an offset of the metal surface from the measurement apparatus.

Furthermore, a typical subregion 1710 is also marked off in the region 1709 shown in FIG. 17 and was subjected to a separate roughness analysis. Within this subregion 1710, the value of the offset of the Z coordinate, which once again has no meaning, is −388.90 nm. The greatest absolute height, i.e. the maximum distance between the lowest point and the highest point within the subregion 1710, is 0.951 nm. The mean roughness of the surface within the subregion 1710 is 0.105 nm, whereas the standard deviation of the roughness is 0.133 nm.

It can be seen from the analysis of the roughness of the specimen of a multilayer arrangement having a metal layer that by means of the process according to the invention it is possible to achieve a metal surface with a very low roughness of less than 0.5 nm. In the case of the specimen produced, the resulting roughness value was slightly more than 0.1 nm, in particular with an RMS value of 0.133 nm.

1-14. (canceled)

15. A process for producing a multilayer arrangement having a metal layer in a molecular electronic arrangement, comprising the steps of:
applying the metal layer to a surface of a first wafer;
applying at least one interlayer to the metal layer;
applying a second wafer to the interlayer; and
removing the first wafer, so that the metal layer is uncovered.

16. The process as claimed in claim 15, wherein the metal layer includes gold, silver, or platinum.

17. The process as claimed in claim 15, wherein the first wafer and/or the second wafer is produced from at least one of the materials from the group consisting of silicon, gallium arsenide, silicon-germanium, indium-gallium arsenide, indium-antimony, zinc sulfide, gallium-aluminum arsenide, gallium-aluminum phosphide, and gallium phosphide.

18. The process as claimed in claims 15, wherein the second wafer includes electronic components.

19. The process as claimed in claim 15, wherein the metal layer is formed as a structured metal layer.

20. The process as claimed in claim 15, further comprising the step of, before applying the metal layer, forming a mask from an electrically insulating material on the surface of the first wafer.

21. The process as claimed in claim 20, wherein the mask is formed from silicon nitride, silicon oxide, hafnium oxide, or aluminum oxide.

22. The process as claimed in claim 15, further comprising the step of forming a further metal layer on the metal layer prior to the step of applying the at least one interlayer.

23. The process as claimed in claim 22, wherein the further metal layer includes titanium, palladium, chromium, or hafnium.

24. The process as claimed in claim 15, wherein the step of applying the second wafer is conducted via wafer bonding.

25. The process as claimed in claim 15, further comprising the step of etching the first wafer.

26. The process as claimed in claim 15, wherein the interlayer is produced from an epoxy resin.

27. The process as claimed in claim 26, wherein the step of applying the second wafer is conducted via adhesive bonding.

28. The process as claimed in claim 26, further comprising the step of stripping the first wafer.

29. The process as claimed in claim 15, further comprising the step of forming a protective layer over the entire surface of the second wafer before the second wafer is applied to the interlayer.

30. The process as claimed in claim 15, further comprising the step of forming a silicon nitride layer on the surface of the first wafer prior to the step of applying the metal layer.

31. The process as claimed in claim 30, further comprising the steps of:
applying a photoresist layer to the silicon nitride layer; and
patterning the photoresist layer and the silicon nitride layer.

32. The process as claimed in claim 31, wherein the metal layer is applied to the surface of the first wafer such that the metal layer does not form a continuous layer, and side faces of the photoresist layer do not contact the metal layer.

33. The process as claimed in claim 32, further comprising the step of forming a further metal layer on the metal layer, wherein the further metal layer does not form a continuous layer, and the side faces of the photo resist layer do not contact the further metal layer.

33. The process as claimed in claim 33, further comprising the step of removing the photoresist layer.
